(19) United States
(12) Patent Application Publication
(10) Pub. No.: US 2004/0137214 A1
(43) Pub. Date: Jul. 15, 2004

(54) Material with surface nanometer functional structure and method of manufacturing the same

(76) Inventors: I-Cherng Chen, Hsinchu (TW); Yung-Kuan Tseng, Hsinchu (TW); Tzer-Shen Lin, Hsinchu (TW)

Correspondence Address: BIRCH STEWART KOLASCH & BIRCH, PO BOX 747, FALLS CHURCH, VA, 22040-0747, US

(21) Appl. No.: 10/690,503

(22) Filed: Oct. 23, 2003

(30) Foreign Application Priority Data
Oct. 25, 2002 (TW) 91125299

(51) Int. Cl. C23C 16/00; B32B 1/00

(52) U.S. Cl. 428/323; 427/226; 427/248.1; 428/195.1; 428/332; 428/401; 428/397; 428/403

(57) ABSTRACT

The specification discloses a material with a surface nanometer functional structure and the method of manufacturing the same. Using the properties of supercritical fluids, a nanometer structure is formed on the surface of a substrate, resulting in a material with a surface nanometer functional structure. The supercritical fluid carries the precursor of functional materials. Once they reach a reaction balance with the substrate in a high-pressure container, the pressure is released at an appropriate speed. The carbon dioxide supercritical fluid undergoes a vaporization reaction, distributing and adhering the precursors on the substrate to form the surface nanometer functional structure. Utilizing the VLS nanowire growth method, one-dimensional and two-dimensional compound nanometer functional wire structure can be produced.

### BACKGROUND OF THE INVENTION

1. Field of Invention

The invention relates to a material machining method and, in particular, to a material with a surface functional structure and the method of manufacturing the same.

2. Related Art

The nanotechnology is a science that uses nanometer (1 nanometer=10⁻⁹ meter) materials to make improvements in various fields. This is an ultimate miniaturization technology. When the material size is as small as nanometers, atoms in the materials are almost on the surface. Strange surface effects, volume effects and quantum effects are expected to appear. The optical, thermal, electrical, magnetic, mechanic or even chemical properties of such nano-scale materials will be very different from those at the macroscopic scales. If the nanometer materials can be well understood and controlled, they will provide a new technology bringing us revolutionary changes. The nanotechnology will not only affect high-tech industries such as information and electronics, it will also have a lot of useful applications in textile engineering, steel, painting, chemical engineering, and even medical or medication fields.

The nanometer materials can be categorized into nanopowders, nanowires, nanomembranes, and nanoblocks. Currently, methods of synthesizing various kinds of nanomaterials have been developed. In particular, the development time of nanopowders is the longest and the most mature. However, we face great difficulty in synthesizing and making functional nanomaterials. This is the bottleneck of nanotechnology applications nowadays. The one-dimensional nanostructures, such as nanotubes, nanowires, and nanorods, have special structures. It is very challenging to form nanowires with surface functional layers.

There are many synthesis methods for nanowires. Currently, people often use the template assisted growth method. It uses a material with nano-scale holes as the template and makes deposition inside the holes to form the nanowires. The nano-scale template is formed from various kinds of materials using different methods. For example, the anodic alumina membranes (AAM) assisted growth method uses the anode oxidation method to form porous alumina with nano-scale holes. Besides, there are also researches that use carbon tubes or porous polymer material as the template to deposit nanowires. However, the manufacturing and design of the nano-scale template required in the template assisted growth method are difficult. The nanostructures are likely to have coalition and diffusion with the template in subsequent thermal processing steps. There are also problems such as etching and mold separation. Therefore, the manufacturing and quality control are very complicated.

The growth method that utilizes the vapor-liquid-solid (VLS) reaction mechanism can grow crystalline inorganic wires. In the 1960s, R. S. Wagner et al. (Appl. Phys. Lett. 1964,4, 89) reported the use of metal clusters as the catalyst for vapor reactants to adhere thereon, forming a liquid alloy. The process of continuously adhering reactant vapors into the liquid alloy results in supersaturated deposition that produces one-dimensional materials. Currently, most researches focus on the systems of silicon and groups III-V semiconductors. Recently, more people are starting to study oxide nanowires, including silicon dioxides, germanium oxides, zinc oxides, indium tin oxides (ITO), and alumina. The VLS method can also be used in the growth of carbon nanotubes and semiconductor nanowires or wide energy gap materials. For example, the GaN nanowires can be effectively grown using the VLS method. The advantage of using this mechanism to grow nanowires is that one can use the catalyst granular size to control the diameter of the nanowires. Besides, one can selectively grow nanotubes or nanowires on a substrate by selective deposition of catalyst thin films or granules. Although the steps in this method are simpler, there are limitations to the materials. Only a few inorganic nanowires can be grown using this method. Moreover, there are technical difficulties in forming nanowires with surface functional layers using the template assisted growth method, the VLS method or other one-dimensional nanostructure manufacturing methods. In the literature (see M. Huang et al. Adv. Mater. 2001,13, 113), people use vacuum evaporation or sputtering to coat a thin gold film with a thickness between 30 Å and 50 Å on the substrate. Afterwards, it is processed at a temperature between 300° C. and 400° C. into minute gold particles in island distributions as the catalyst in the VLS method for growing nanowires. They mix graphite and zinc oxide and heat at a temperature between 900° C. and 925° C. to grow nanowires. Alternatively, they also use hydrogen to reduce zinc oxide to zinc vapor. Under a temperature between 525° C. and 650° C., zinc oxide nanowires are grown on the substrate. The drawback of the manufacturing process is that it has to be performed under high temperatures.

The invention utilizes supercritical fluid carriage and tuning organic metal precursor solution concentration to distribute its action on an appropriate substrate. Nano-scale metal granules are formed on the substrate without thermal processing. It can achieve good processing distribution effects on rough substrate surfaces with irregular shapes or complicated holes. The substrate thus processed can be grown with nanowires on various kinds of irregular geometrical shapes and complicated structures using the VLS method. Moreover, the above-mentioned substrate with the nanowire structures can be further processed using supercritical fluid carriage and organic metal precursors along with the VLS method to achieve one with clustered nanowires.

The nanostructures obtained using above-mentioned manufacturing methods for several related surface nanometer functional structures include nanoparticle distribution adhesion structures on a substrate surface, nanowire structures on a substrate surface, and clustered nanowire structure on a substrate surface. With the process of using supercritical fluid carriage functional material precursor on nanowire surface functional layers, there is great potential in applying nanometer ultrahigh surface area/volume ratio to highly effective catalyst and biomedical examinations.

### SUMMARY OF THE INVENTION

To solve problems in the prior art and to further enhance the nanomaterial properties for forming functional nanomaterials, the invention provides a material with surface nanometer functional structures and the method of manufacturing the same. Utilizing the features of supercritical fluid, a surface nanometer functional structure is formed on a substrate.

The invention utilizes supercritical fluid carriage and tuning organic metal precursor solution concentration to distribute its action on an appropriate substrate. Nano-scale metal granules are formed on the substrate without thermal processing. It can achieve good processing distribution effects on rough substrate surfaces with irregular shapes or complicated holes. The substrate thus processed can be grown with nanowires on various kinds of irregular geometrical shapes and complicated structures using the VLS method. Moreover, the above-mentioned substrate with the nanowire structures can be further processed using supercritical fluid carriage and organic metal precursors along with the VLS method to achieve one with clustered nanowires.

The nanostructures obtained using above-mentioned manufacturing methods for several related surface nanometer functional structures include nanoparticle distribution adhesion structures on a substrate surface, nanowire structures on a substrate surface, and clustered nanowire structure on a substrate surface. With the process of using supercritical fluid carriage functional material precursor on nanowire surface functional layers, there is great potential in applying nanometer ultrahigh surface area/volume ratio to highly effective catalyst and biomedical examinations.

When gas exceeds a certain critical pressure Pc and a critical temperature Tc, it becomes a supercritical fluid. The supercritical fluid is similar to regular fluids in density, diffusion coefficient, but is similar to gases in viscosity, high reaction speed, and extremely low (almost zero) surface tension. Due to the high permittivity of supercritical fluids, they are often used in abstraction, pigmentation, and film forming by deposition. In general, commonly used supercritical fluids include NH₃, H₂O, N₂O, methanol, and CO₂. The invention utilizes the permittivity property of the supercritical fluid to have the supercritical fluid carry the precursor of functional materials. They are then distributed to adhere on substrate surfaces of different shapes and sizes, forming various kinds of surface nanometer functional structures.

According to the steps of the invention, the substrate is first placed in a high-pressure container, which is then filled with a supercritical fluid such as carbon dioxide. In accordance with the organic precursor of the functional material to be added, an appropriate solution adjusts its polarity and maintains the temperature and pressure inside the high-pressure container within a proper range. The organic precursor of the functional material is then sent into the high-pressure container. After the fluid inside the container reach its reaction balance point, the pressure inside the container is released at an appropriate speed. The supercritical fluid correspondingly undergoes a vaporization reaction, making the precursor adhere onto the surface of the substrate and forming a surface nanometer functional structure. The supercritical fluid is in a non-polarized solution state and has a good solubility with the precursor of the target material. Moreover, the strong permittivity of the supercritical fluid is convenient for distributing precursors on irregular substrate surface with nano-scale holes or a micro arrayed structure. The operating temperature of carbon dioxide can be as low as about zero degree of Celsius. This can avoid damages to the substrate surface, and can be readily applied to biomedicines and biotechnologies. There are more choices in the supercritical fluids in other fields.

When using the supercritical fluid assisted technology to prepare materials with surface nanometer functional structures, there are little constraints in the substrate and the materials for forming the functional structures. At the same time, one can utilize manufacturing procedure design, pre-processing of the substrate, and the precursor solution to control the surface nanometer functional structure to be formed. For example, one can form several micro nanowires, nanoparticles, or homogeneous functional layers (such as the molecule self-assembling reaction layers) on the substrate surface. The surface nanometer functional structure can be made of organic molecules, metal oxides, non-metal oxides, or metals.

### BRIEF DESCRIPTION OF THE DRAWINGS

The invention will become more fully understood from the detailed description given hereinbelow illustration only, and thus are not limitative of the present invention, and wherein:

FIG. 1 is a flowchart of the manufacturing procedure according to an embodiment of the invention;

FIG. 2 is a schematic view of the supercritical fluid system;

FIG. 3 is an electronic microscopic view of the surface nanometal functional structure;

FIG. 4 is an electronic microscopic view of the surface zinc oxide nanowire structure;

FIG. 5 is an X-ray thin-film crystal diffraction diagram of the zinc oxide nanowires on an alumina substrate surface;

FIG. 6 is an electronic microscopic view of the nanometal particle structure on the surface of zinc nanowires;

FIG. 7 is an electronic microscopic view of clustered nanowire structure on the surface of zinc nanowires; and

FIG. 8 is an electronic microscopic view of the spiked ball structure formed from zinc nanowire clusters grown on silicon dioxide powders.

### DETAILED DESCRIPTION OF THE INVENTION

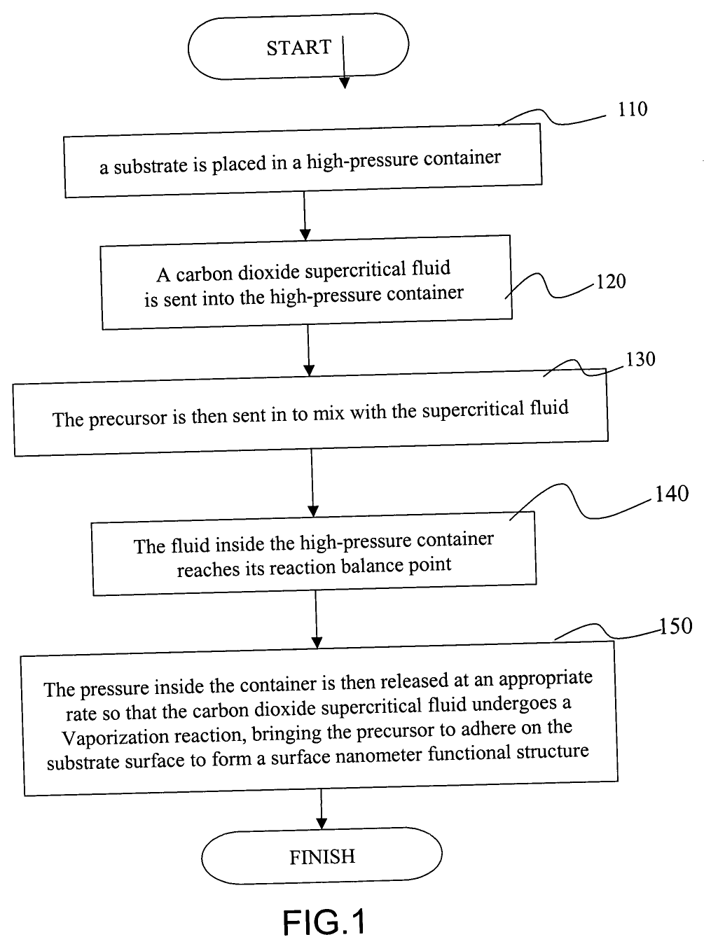

With reference to FIG. 1, the steps in an embodiment of the invention are as follows. First, a substrate is placed in a high-pressure container (step 110). A carbon dioxide supercritical fluid is sent into the high-pressure container (step 120). In accordance with the precursor to be added, the temperature and pressure inside the high-pressure container are tuned to their appropriate values. The precursor is then sent in to mix with the supercritical fluid (step 130). The fluid inside the high-pressure container reaches its reaction balance point (step 140). The pressure inside the container is then released at an appropriate rate so that the carbon dioxide supercritical fluid undergoes a vaporization reaction, bringing the precursor to adhere on the substrate surface to form a surface nanometer functional structure (step 150). The temperature and pressure inside the high-pressure container are determined by the reacting precursor. For example, the preferred temperature for organic materials is about 40 degrees of Celsius and the preferred pressure is 3000 psi.

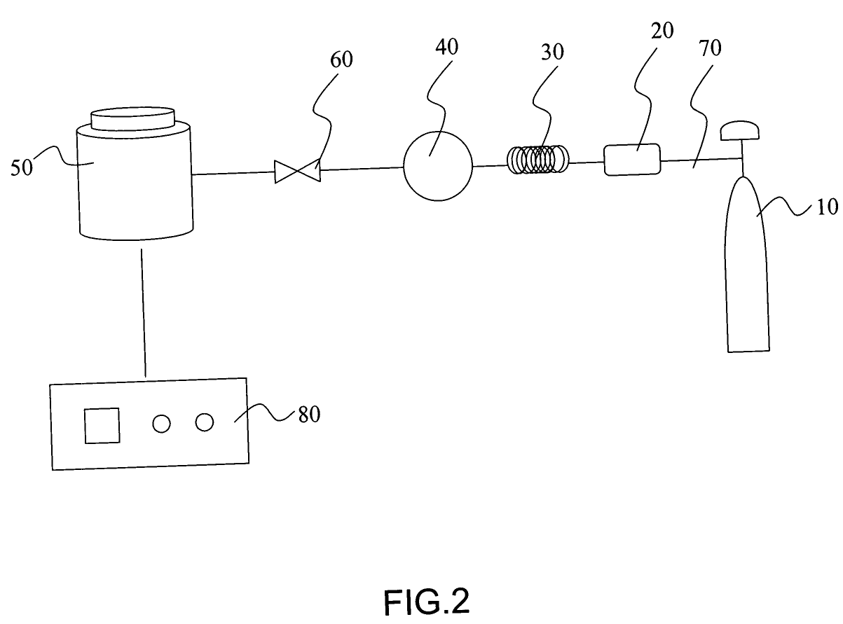

The manufacturing method for materials with surface nanometer functional structure has to be implemented with a supercritical fluid system. FIG. 2 shows a schematic view of the supercritical fluid system. The system includes a supercritical fluid source 10, a buffer region 20, a cooling device 30, a pump 40, a high-pressure container 50, a control valve 60, a fluid pipe 70, and an auto controller 80. The supercritical fluid source 10 provides the carbon dioxide supercritical fluid. The fluid operating temperature can be as low as about zero degree of Celsius. The motion of the carbon dioxide supercritical fluid is achieved by the pump. The reaction path is as follows. The supercritical fluid is output from supercritical fluid source 10 to the fluid pipe 70. It then passes the buffer region 20 and the cooling device 30 to maintain its low temperature. Afterwards, the control valve 60 is opened for the supercritical fluid to enter the high-pressure container 50 that contains the precursor and the substrate. The auto controller adjusts the temperature and pressure inside the container 50 to their appropriate values, thereby allowing the precursor and substrate to have reactions. Finally, after the fluid inside the container 50 reaches its reaction balance, the pressure is released at an appropriate rate. The carbon dioxide supercritical fluid undergoes a vaporization reaction, bringing the precursor to adhere on the substrate surface to form the surface nanometer functional structure. The complete reaction procedure is controlled by the auto controller 80.

The precursor of the functional material in the disclosed manufacturing method can be made from alcohol compounds, acetates, resins, or 2-ethyl-hexanoic acid compounds diluted with a solution, according to their individual properties. If the precursor is alcohols and acetates of the target material, the solution can be methanol, acetone, capric acid, 2-ethyl-hexanoic acid, ethanol, or propanol. If the precursor is resins and 2-ethyl-hexanoic acid compounds, the solution can be 2-ethyl-hexanoic acid and diphenylmethane. The precursor can be made from acetone compounds of the target material diluted by an acetone solution or a mixture of the nanoparticles of the target material and an interface activator.

The invention can utilize various kinds of manufacturing process designs, pre-processing, and precursor solutions to control the growth of different types and ingredients of surface nanometer functional structures. We herein provide five embodiments as follows.

### Embodiment 1

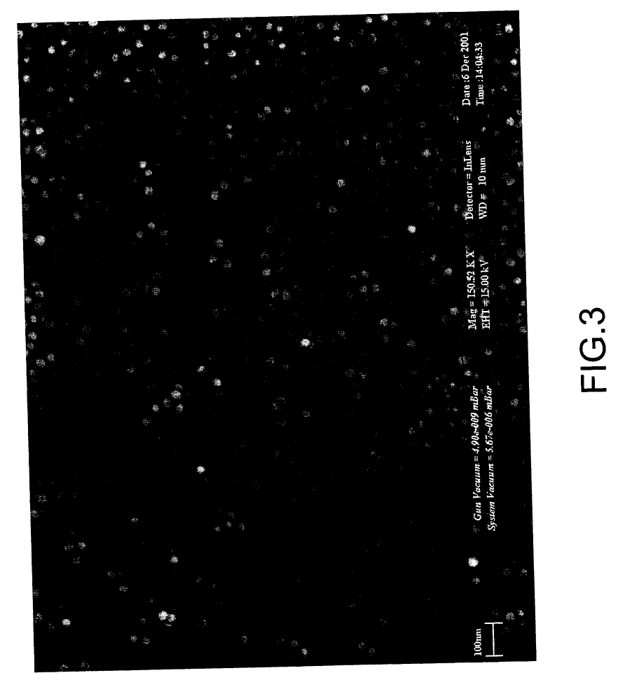

The invention uses alumina (96%, thick film grade) as the substrate. It is placed in a 5-liter stainless steel high-pressure container. 0.05 g metal resin is mixed with 100 ml diphenylmethane into a homogeneous solution and added to the container. We then supply carbon dioxide supercritical fluid into the container, maintaining the reaction temperature and pressure at 40 degrees of Celsius and 3000 psi, respectively, until the fluid reaches its reaction balance point. After one to three hours, the pressure inside the container is released for the carbon dioxide supercritical fluid to undergo a vaporization reaction. The nanometal adheres onto the substrate surface to form a nanometer functional structure. The electronic microscopic view of the result is shown in FIG. 3.

### Embodiment 2

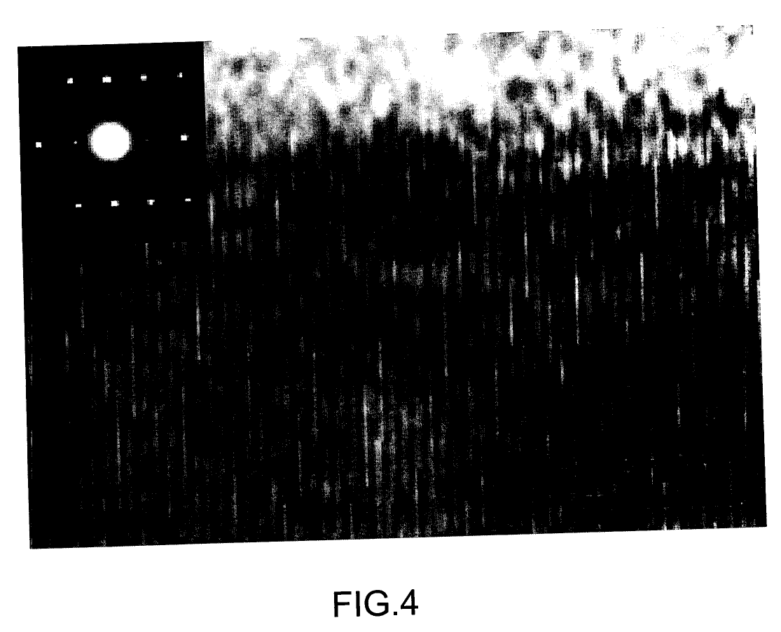

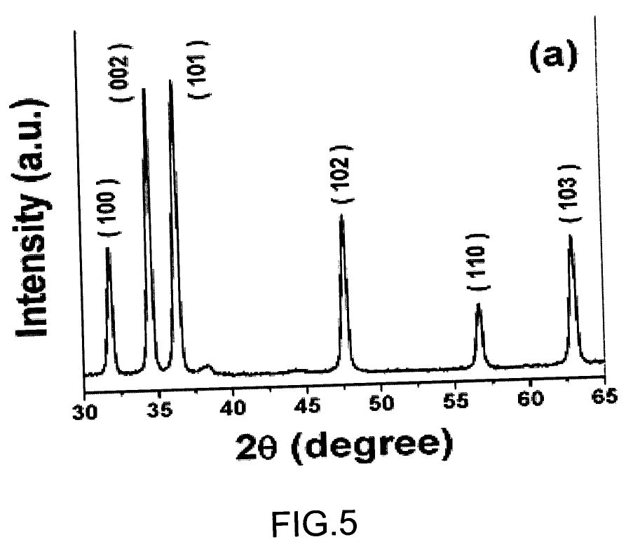

The operations in the disclosed VLS growth method for synthesizing zinc oxide nanowires are mainly featured with furnace along with highly pure zinc vapor production and low oxidization environment controls. The experiment starts by mixing zinc oxide (99.999%, 350 mesh, Strem Chemicals) with zinc metal powders (99.999%, 350 mesh, Strem Chemicals) at the 1:1 mole ratio. The mixture is placed in an alumina silica shell, which is then disposed at the front position of the heating part of a quartz tube in the reaction system. The substrate is made of alumina (96%, thick film grade) or alumina sapphire (100) implanted with nanometer metal catalysts using a supercritical fluid (see Embodiment 1). The substrate is then disposed at the rear position of the heating part of a quartz tube in the reaction system. 20-100 sccm argon mixed with very little water or 1% oxygen is supplied in the experiment. A mechanical pump controls the vacuum of the reaction system at about 20-300 Torr. The furnace temperature is raised to 500° C.-700° C. The reaction time is about 30 to 60 minutes. At the end of the reaction, zinc oxide nanowires are formed. The FESEM (LEO 1530, operated at 5 keV) is used to observe the nanometer structure on the substrate surface. The result is shown in FIG. 4. We also use the X-ray diffraction device (XRD Philips PW3710 type) to analyze the crystal structure of the zinc oxide nanowires. The diffraction pattern is shown in FIG. 5. Its vertical axis is the diffraction intensity, while its horizontal axis is the diffraction peak angle 2θ.

### Embodiment 3

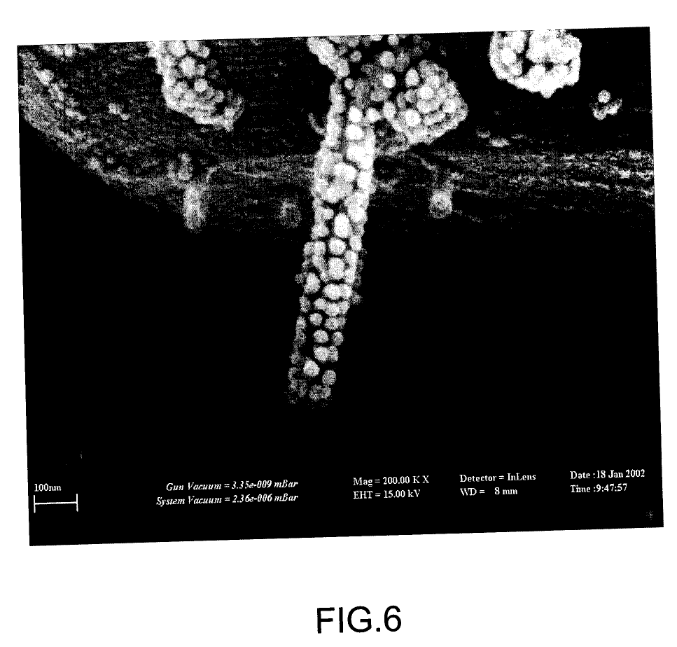

Combining Embodiment 1 and Embodiment 2, the alumina grown with zinc oxide nanowires is taken as the substrate (see Embodiment 2). We use carbon dioxide supercritical fluid to carry organic metal precursor to process the substrate (see Embodiment 1). We are able to grow nanometal particles (10˜30 nm) on the zinc oxide nanowires (70˜100 nm). Please refer to FIG. 6 for an electronic microscopic view of the nanometal particle structure on the surface of the zinc oxide nanowires.

### Embodiment 4

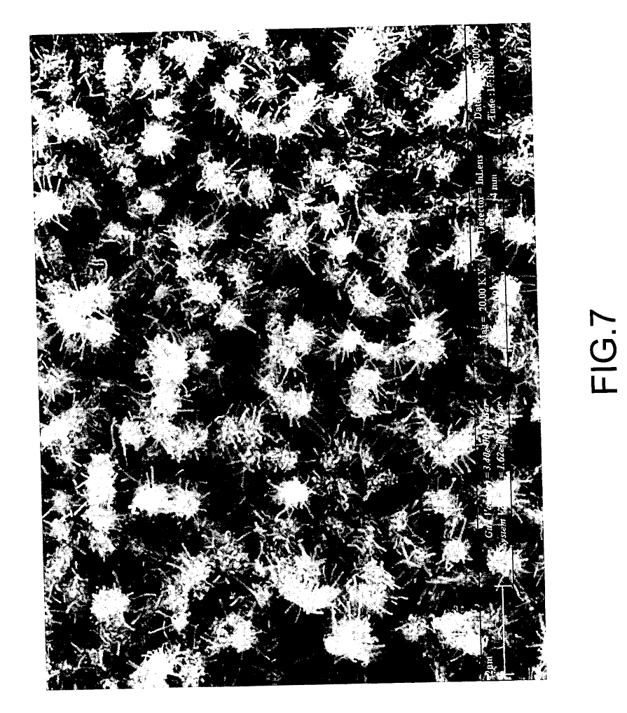

The alumina substrate with surface nanometal decorated zinc nanowires (see Embodiment 3) is processed using the VLS growth method (see Embodiment 2), we can obtain a substrate with a clustered nanowire structure. The result is shown in FIG. 7.

### Embodiment 5

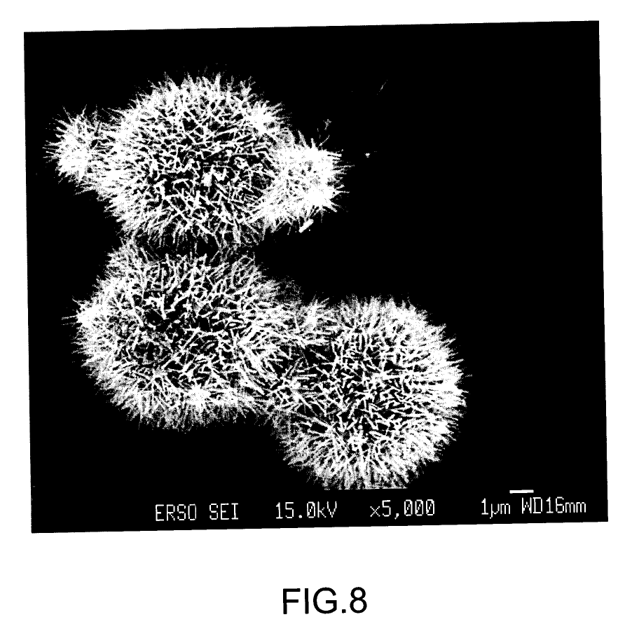

We take 12 μm silicon dioxide powders and use nickel nitric acid dissolved in methanol to form a 0.001-0.1M solution as the precursor. The substrate processing of using the carbon dioxide supercritical fluid to carry the catalyst precursor is shown in Embodiment 1. The VLS growth method is given in Embodiment 2. Finally, the zinc oxide nanowire clusters are grown into spiked ball structures on silicon dioxide powders. The electronic microscopic view is shown in FIG. 8.

When using the supercritical fluid assisted technology to prepare materials with surface nanometer functional structures, the substrate and materials for forming functional structures are not limited. One can form various kinds of surface nanometer functional structures on ultrahigh surface area to volume ratio nanometer materials or one-dimensional nanometer structures. In particular, one can form different kinds of functional structures on one-dimensional nanometer structures that are difficult for machining (such as nanowires). From the above-mentioned embodiments, we see that the substrate can be selected from inorganic substrates, polymer substrates, inorganic powders, or polymer powders. Their surfaces can have irregular structure with micrometer-scale holes and nanometer-scale holes. At the same time, the growth of surface nanometer functional structures can be controlled through manufacturing procedure designs, substrate preprocessing, and precursor solution preparation.

Moreover, if the material with a surface nanometer functional structure further goes through subsequent processes, such as the VLS growth method and thermal processing, the functions of its surface nanometer functional structure can be further enhanced. Repeating the supercritical fluid processing procedure can make multi-layer compound surface nanometer functional structures. Along with the repeated VLS growth method, one can build up extra branches of wire structures on the primitive wire structure. The surface nanometer functional structure can be formed from organic molecules, metal oxides, non-metal oxides or metals. In summary, the invention has potential applications in multiple functional nanometer structures.

Certain variations would be apparent to those skilled in the art, which variations are considered within the spirit and scope of the claimed invention.

What is claimed is:

1. A manufacturing method for a material with a surface nanometer functional structure, which comprises the steps of:
(a) providing a substrate and placing it in a high-pressure container;
(b) supplying a supercritical fluid into the high-pressure container;
(c) tuning the temperature and pressure inside the high-pressure container to their appropriate values;
(d) supplying a precursor of a target material to be formed with a surface nanometer functional structure to the high-pressure container; and
(e) releasing the pressure inside the high-pressure container after the fluid therein reaches its reaction balance point, bringing the precursor to adhere on the substrate surface to form the surface nanometer functional structure.

2. The manufacturing method of claim 1, wherein the supercritical fluid is carbon dioxide supercritical fluid.

3. The manufacturing method of claim 1, wherein the supercritical fluid is selected from the group consisting of NH₃, H₂O, N₂O, methanol, CO₂.

4. The manufacturing method of claim 1 further comprising the step of performing a subsequent processing procedure on the surface nanometer functional structure on the substrate surface to enhance its functions.

5. The manufacturing method of claim 1, wherein the subsequent processing procedure is selected from a vapor-liquid-solid (VLS) growth method and thermal processing on the surface nanometer functional structure.

6. The manufacturing method of claim 1, wherein the substrate is selected from the group consisting of inorganic substrates, polymer substrates, inorganic powders, and polymer powders.

7. The manufacturing method of claim 1, wherein the surface of the substrate has combinations of micrometer-scale holes, nanometer-scale holes, and irregular surface structure.

8. The manufacturing method of claim 1, wherein the precursor is made from a compound selected from the group consisting of alcohol compounds, acetates, resins, or 2-ethyl-hexanoic acid compounds of the target material diluted with a solution.

9. The manufacturing method of claim 8, wherein the solution is selected from the group consisting of methanol, acetone, capric acid, 2-ethyl-hexanoic acid, ethanol, and propanol when the precursor is in the group consisting of alcohols and acetates of the target material.

10. The manufacturing method of claim 8, wherein the solution is selected from the group consisting of 2-ethyl-hexanoic acid and diphenylmethane when the precursor is in the group consisting of resins and 2-ethyl-hexanoic acid compounds.

11. The manufacturing method of claim 1, wherein the precursor is made by the acetone compounds of the target material diluted by an acetone solution.

12. The manufacturing method of claim 1, wherein the precursor is a solution of mixed nanoparticles and an interface activator.

13. The manufacturing method of claim 1 further comprising the step of forming a plurality of catalyzing growth points on the inorganic nanowire surface by supplying a catalyst precursor into the high-pressure container before step (d).

14. The manufacturing method of claim 1 further comprising the step of repeating steps (b) to (e) after step (e) to form a multi-layer compound surface nanometer functional structure.

15. The manufacturing method of claim 1, wherein the surface nanometer functional structure includes a plurality of micro nanowires.

16. The manufacturing method of claim 1, wherein the nanometer functional structure includes a plurality of nanodots.

17. The manufacturing method of claim 1, wherein the surface nanometer functional structure is a homogeneous functional layer.

18. The manufacturing method of claim 17, wherein the functional layer is a molecule self-assembling reaction layer.

19. The manufacturing method of claim 1, wherein the material of the surface nanometer functional structure is selected from the group consisting of organic molecules, metal oxides, non-metal oxides, and metals.

20. A material with a surface nanometer functional structure comprising:
a substrate; and
more than one layer of surface nanometer functional structure formed on the substrate surface.

21. The material of claim 20, wherein the substrate is a nanometer material with an ultrahigh surface area to volume ratio.

22. The material of claim 20, wherein the surface nanometer functional structure includes a plurality of micro nanowires.

23. The material of claim 20, wherein the surface nanometer functional structure includes a plurality of nanodots.

24. The material of claim 20, wherein the surface nanometer functional structure is a homogeneous functional layer.

25. The material of claim 24, wherein the functional later is a molecule self-assembling reaction layer.

26. The material of claim 20, wherein the material of the surface nanometer functional structure is selected from the group consisting of organic molecules, metal oxides, non-metal oxides, and metals.

27. A one-dimensional nanometer material with a surface nanometer functional structure, which comprises:
a nanowire; and
more than one layer of surface nanometer functional structure formed on the substrate surface.

28. The material of claim 27, wherein the surface nanometer functional structure includes a plurality of micro nanowires.

29. The material of claim 27, wherein the surface nanometer functional structure includes a plurality of nanodots.

30. The material of claim 27, wherein the surface nanometer functional structure is a homogeneous functional layer.

31. The material of claim 27, wherein the material of the surface nanometer functional structure is selected from the group consisting of organic molecules, metal oxides, non-metal oxides, and metals.
